(19) United States
(12) Patent Application Publication
(10) Pub. No.: US 2017/0222616 A1
(43) Pub. Date: Aug. 3, 2017

(54) BRANCHING FILTER

(71) Applicant: TDK CORPORATION, Tokyo (JP)

(72) Inventors: Manabu KITAMI, Tokyo (JP); Kazuhiro TSUKAMOTO, Tokyo (JP)

(73) Assignee: TDK CORPORATION, Tokyo (JP)

(21) Appl. No.: 15/386,413

(22) Filed: Dec. 21, 2016

(30) Foreign Application Priority Data
Jan. 29, 2016 (JP) 2016-015661

(51) Int. Cl. H03H 7/46; H03H 7/01

(52) U.S. Cl. CPC H03H 7/46; H03H 7/0115

(57) ABSTRACT

A branching filter includes a first filter provided between a common port and a first signal port, and a second filter provided between the common port and a second signal port. The branching filter further includes a connection path and a first capacitor. The connection path includes a first inductor, and connects the common port and the first filter. The first capacitor is provided between the connection path and the ground. The second filter is connected to the connection path. The first capacitor is connected to the first inductor at a first branch point located at any position in the first inductor.

### BACKGROUND OF THE INVENTION

1. Field of the Invention

The present invention relates to a branching filter for separating a plurality of signals of mutually different frequencies from each other.

2. Description of the Related Art

Recently, compact mobile communication apparatuses have achieved greater functionality and multisystem (multiband) capability. From the viewpoint of reducing size, footprint and cost, such compact mobile communication apparatuses are generally configured to use a single common antenna for a plurality of applications that use different systems and have different service frequency bands, and to use a branching filter to separate a plurality of signals received and transmitted by the antenna from each other.

Typically, a branching filter for separating two signals in mutually different frequency bands from each other includes a common port, a first signal port, a first filter provided between the common port and the first signal port, and a second filter provided between the common port and the second signal port.

The recent market demands for reductions in size and footprint of the compact mobile communication apparatuses have also required miniaturization of branching filters for use in those communication apparatus. Among known branching filters suited for miniaturization are ones that use a stack of dielectric layers and conductor layers, as disclosed in JP 2006-093996A.

Some of the branching filters using such a stack have a configuration in which the branch point between the path to the first filter and the path to the second filter as viewed from the common port is located away from the common port, and there is a common path connecting the common port and the branch point. In such branching filters configured with the stack, a path including the common path and leading to at least one of the two filters from the common port may include a plurality of through holes serially connected to each other. Hereinafter, a set of serially connected through holes will be referred to as a through hole line. For the branching filter in which a plurality of terminals including one corresponding to the common port are provided on the bottom surface of the stack, there are cases where the path leading to at least one of the two filters from the common port must be formed using a relatively long through hole line.

Through hole lines have inductances. Thus, in the branching filter in which the path leading to at least one of the two filters from the common port is formed using a through hole line, the inductance of the through hole line can cause an impedance mismatch between the common port and the at least one of the two filters, thereby causing degradation in the performance of the branching filter as compared to that as designed.

### SUMMARY OF THE INVENTION

It is an object of the present invention to provide a branching filter that exhibits favorable characteristics even when a path leading to at least one of two filters from a common port has an inductance.

A branching filter of the present invention includes a common port, a first signal port, a second signal port, a first filter, a second filter, a connection path, and a first capacitor. The first filter is provided between the common port and the first signal port, and configured to selectively pass a signal of a frequency within a first passband. The second filter is provided between the common port and the second signal port, and configured to selectively pass a signal of a frequency within a second passband different from the first passband. The connection path includes a first inductor, and connects the common port and the first filter. The first capacitor is provided between the connection path and the ground. The second filter is connected to the connection path. The first inductor has a first end closer to the common port and a second end closer to the first filter. The first capacitor is connected to the first inductor at a first branch point located at any position in the first inductor inclusive of the first end and the second end.

In the branching filter of the present invention, the connection path may further include a second inductor provided between the first inductor and the first filter. In such a case, the second filter may be connected to the first inductor at a second branch point located at any position in the first inductor inclusive of the first end and the second end. The first branch point may be located between the first end and the second branch point, inclusive, in the first inductor.

When the connection path includes the second inductor, the branching filter of the present invention may further include a second capacitor. The second capacitor is provided between the first filter and a third branch point located at any position in the first inductor inclusive of the first end and the second end.

The branching filter of the present invention may further include a stack for constructing the first filter, the second filter, the connection path and the first capacitor. The stack includes a plurality of dielectric layers and a plurality of conductor layers stacked on each other. In such a case, the branching filter of the present invention may further include a second capacitor. The second capacitor is constructed of the stack and provided between the first filter and the third branch point located at any position in the first inductor inclusive of the first end and the second end. The first inductor may be constructed of a plurality of through holes connected in series.

In the branching filter of the present invention, the second passband may be a frequency band lower than the first passband.

By virtue of the provision of the first capacitor, the branching filter of the present invention exhibits favorable characteristics even when the path leading to at least one of the two filters from the common port has an inductance.

Other and further objects, features and advantages of the invention will appear more fully from the following description.

### BRIEF DESCRIPTION OF THE DRAWINGS

FIG. 1 is a circuit diagram illustrating the circuit configuration of a branching filter according to an embodiment of the invention.

FIG. 2 is a perspective view illustrating the external appearance of the branching filter according to the embodiment of the invention.

FIG. 3 is a perspective internal view of a stack included in the branching filter shown in FIG. 2.

FIG. 4 is an enlarged perspective view of a portion of the interior of the stack shown in FIG. 3.

FIG. 5A to FIG. 5D are explanatory diagrams illustrating the respective patterned surfaces of the first to fourth dielectric layers of the stack shown in FIG. 2.

FIG. 6A to FIG. 6D are explanatory diagrams illustrating the respective patterned surfaces of the fifth to eighth dielectric layers of the stack shown in FIG. 2.

FIG. 7A is an explanatory diagram illustrating the patterned surface of the ninth dielectric layer of the stack shown in FIG. 2.

FIG. 7B is an explanatory diagram illustrating the patterned surface of each of the tenth and eleventh dielectric layers of the stack shown in FIG. 2.

FIG. 7C and FIG. 7D are explanatory diagrams illustrating the respective patterned surfaces of the twelfth and thirteenth dielectric layers of the stack shown in FIG. 2.

FIG. 8A is an explanatory diagram illustrating the patterned surface of the fourteenth dielectric layer of the stack shown in FIG. 2.

FIG. 8B is an explanatory diagram illustrating the patterned surface of each of the fifteenth to twenty-third dielectric layers of the stack shown in FIG. 2.

FIG. 8C and FIG. 8D are explanatory diagrams illustrating the respective patterned surfaces of the twenty-fourth and twenty-fifth dielectric layers of the stack shown in FIG. 2.

FIG. 9A and FIG. 9B are explanatory diagrams illustrating the respective patterned surfaces of the twenty-sixth and twenty-seventh dielectric layers of the stack shown in FIG. 2.

FIG. 10 is a circuit diagram illustrating the circuit configuration of a branching filter of a first comparative example.

FIG. 11 is a circuit diagram illustrating the circuit configuration of a branching filter of a second comparative example.

FIG. 12 is a characteristic diagram illustrating an example of characteristics of the branching filter of the second comparative example.

FIG. 13 is an explanatory diagram illustrating an example of the impedance characteristic of the branching filter of the second comparative example.

FIG. 14 is a characteristic diagram illustrating an example of characteristics of the branching filter shown in FIG. 1.

FIG. 15 is an explanatory diagram illustrating an example of the impedance characteristic of the branching filter shown in FIG. 1.

### DETAILED DESCRIPTION OF THE PREFERRED EMBODIMENT

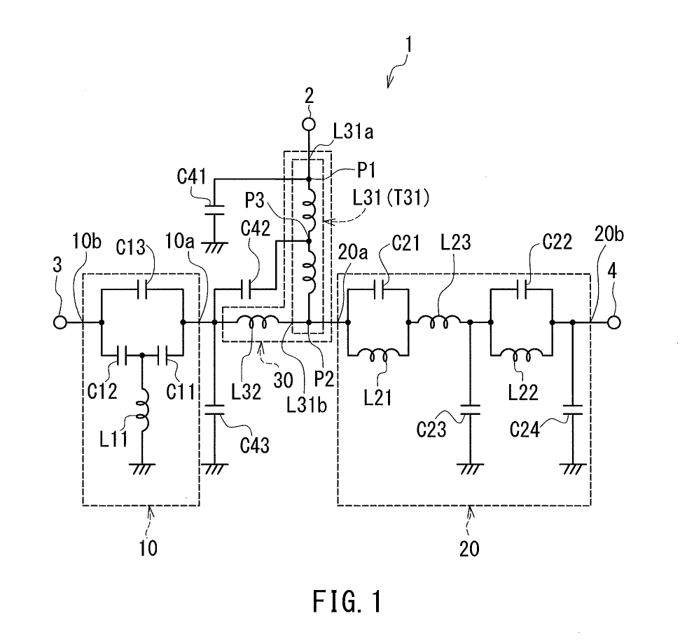

A preferred embodiment of the present invention will now be described in detail with reference to the drawings. First, reference is made to FIG. 1 to describe the circuit configuration of a branching filter according to the embodiment of the invention. The branching filter 1 according to the embodiment is configured to separate a first signal of a frequency within a first frequency band and a second signal of a frequency within a second frequency band different from the first frequency band from each other.

The branching filter 1 according to the embodiment includes a common port 2, a first signal port 3, a second signal port 4, a first filter 10, a second filter 20, a connection path 30, and a first capacitor C41.

The first filter 10 is provided between the common port 2 and the first signal port 3, and configured to selectively pass a signal of a frequency within a first passband. The aforementioned first frequency band may coincide with the first passband or may be part of the first passband. The second filter 20 is provided between the common port 2 and the second signal port 4, and configured to selectively pass a signal of a frequency within a second passband different from the first passband. The aforementioned second frequency band may coincide with the second passband or may be part of the second passband.

In this embodiment, the second passband is a frequency band lower than the first passband. The first filter 10 is a high-pass filter, and the second filter 20 is a low-pass filter.

The connection path 30 includes a first inductor L31 and connects the common port 2 and the first filter 10. The first capacitor C41 is provided between the connection path 30 and the ground. The second filter 20 is connected to the connection path 30.

The first inductor L31 has a first end L31a, which is an end closer to the common port 2, and a second end L31b, which is an end closer to the first filter 10. The first capacitor C41 is connected to the first inductor L31 at a first branch point P1 located at any position in the first inductor L31 inclusive of the first end L31a and the second end L31b.

The connection path 30 further includes a second inductor L32 provided between the first inductor L31 and the first filter 10. The second filter 20 is connected to the first inductor L31 at a second branch point P2 located at any position in the first inductor L31 inclusive of the first end L31a and the second end L31b. The first branch point P1 may be located between the first end L31a and the second branch point P2, inclusive, in the first inductor L31.

The branching filter 1 further includes a second capacitor C42. The second capacitor C42 is provided between the first filter 10 and a third branch point P3 located at any position in the first inductor L31 inclusive of the first end L31a and the second end L31b.

The branching filter 1 further includes a capacitor C43. The capacitor C43 is provided between the ground and the connection point between the connection path 30 and the first filter 10.

The first filter 10 has a first end 10a closer to the common port 2 and a second end 10b closer to the first signal port 3. The first filter 10 includes a capacitor C11 and a capacitor C12 provided between the first end 10a and the second end 10b. The capacitor C11 and the capacitor C12 are arranged in series in this order from the first-end-10a side. The first filter 10 further includes a capacitor C13 and an inductor L11. The capacitor C13 is provided between the first end 10a and the second end 10b. The inductor L11 is provided between the ground and the connection point between the capacitors C11 and C12.

The second filter 20 has a first end 20a closer to the common port 2 and a second end 20b closer to the second signal port 4. The second filter 20 includes an inductor L21, an inductor L23 and an inductor L22 provided between the first end 20a and the second end 20b. The inductors L21, L23 and L22 are arranged in series in this order from the first-end-20a side. The second filter 20 further includes a capacitor C21 connected in parallel to the inductor L21, and a capacitor C22 connected in parallel to the inductor L22. The second filter 20 further includes a capacitor C23 and a capacitor C24. The capacitor C23 is provided between the ground and the connection point between the inductors L23 and L22. The capacitor C24 is provided between the second signal port 4 and the ground.

Now, the path leading to the first signal port 3 from the common port 2 will be referred to as the first signal path, and the path leading to the second signal port 4 from the common port 2 will be referred to as the second signal path. The first signal of a frequency within the first frequency band selectively passes through the first signal path and not through the second signal path. The second signal of a frequency within the second frequency band selectively passes through the second signal path and not through the first signal path.

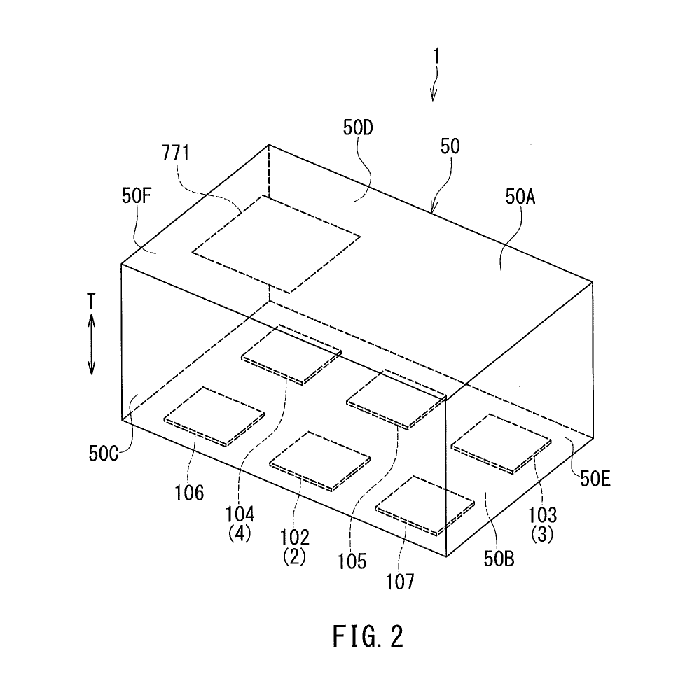

An example of the structure of the branching filter 1 will now be described. FIG. 2 is a perspective view of the branching filter 1. The branching filter 1 shown in FIG. 2 includes a stack 50 for constructing the common port 2, the first signal port 3, the second signal port 4, the first filter 10, the second filter 20, the connection path 30 and the capacitors C41, C42 and C43. As will be described in detail later, the stack 50 includes a plurality of dielectric layers and a plurality of conductor layers stacked on each other.

The stack 50 is shaped like a rectangular solid and has a periphery. The periphery of the stack 50 includes a top surface 50A, a bottom surface 50B, and four side surfaces 50C, 50D, 50E and 50F. The top surface 50A and the bottom surface 50B are opposite each other. The side surfaces 50C and 50D are opposite each other. The side surfaces 50E and 50F are opposite each other. The side surfaces 50C to 50F are perpendicular to the top surface 50A and the bottom surface 50B. In the stack 50, the plurality of dielectric layers and the plurality of conductor layers are stacked in the direction perpendicular to the top surface 50A and the bottom surface 50B. This direction will be referred to as the stacking direction. The stacking direction is shown by the arrow T in FIG. 2.

The branching filter 1 shown in FIG. 2 has a common terminal 102, a first terminal 103, a second terminal 104, and three ground terminals 105, 106 and 107. The terminals 102, 103 and 104 correspond to the common port 2, the first signal port 3 and the second signal port 4 shown in FIG. 1, respectively. The ground terminals 105, 106 and 107 are connected to the ground. The terminals 102 to 107 are provided on the bottom surface 50B of the stack 50.

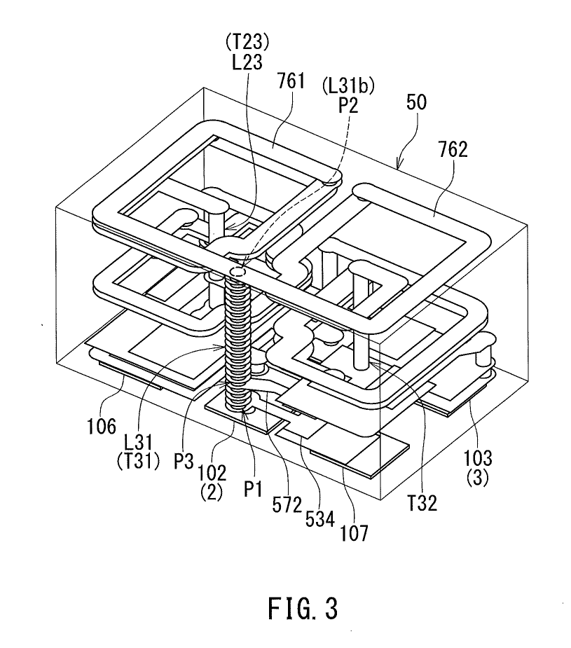

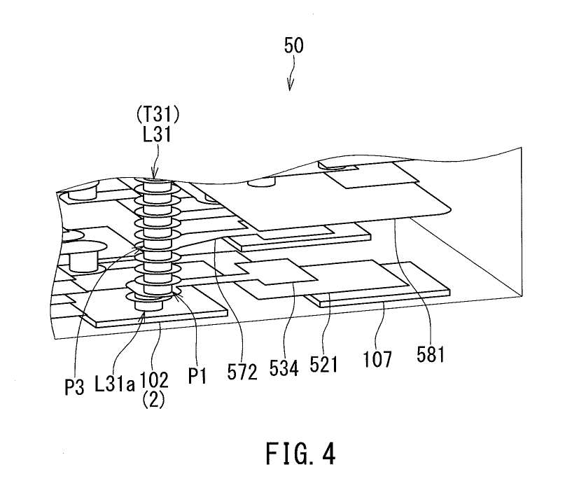

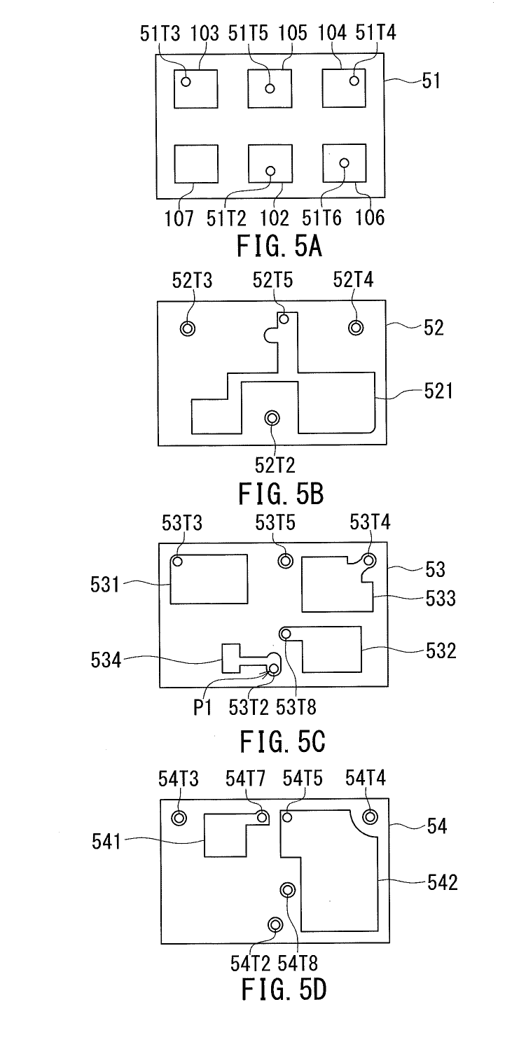

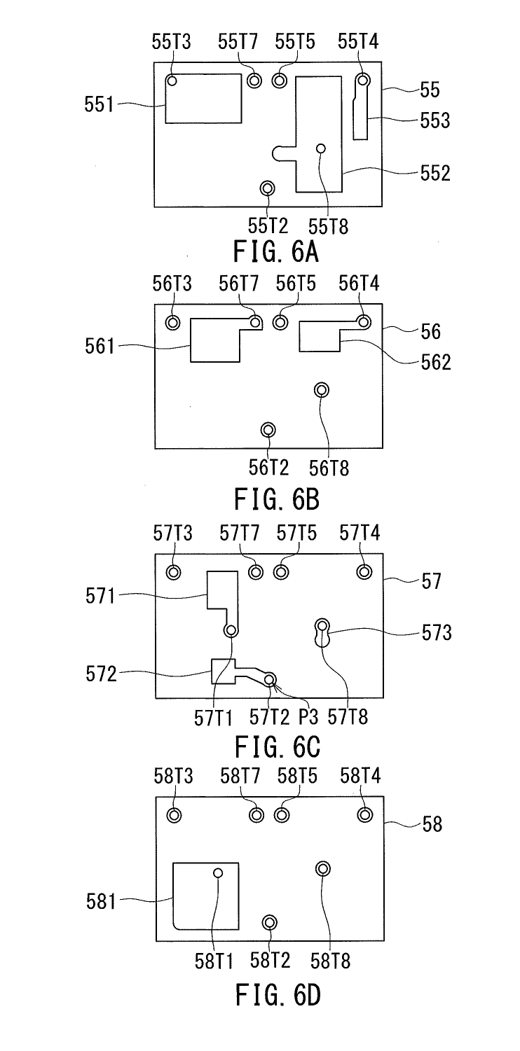

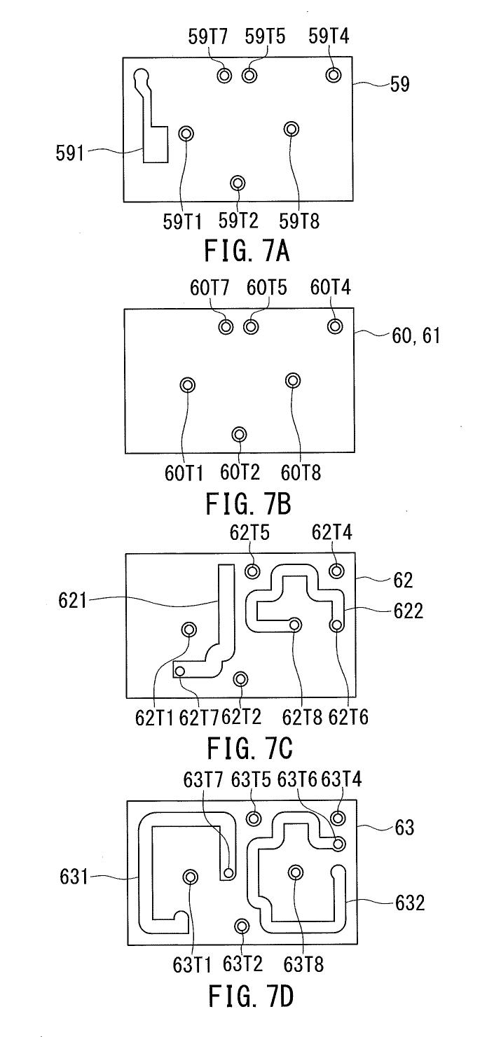

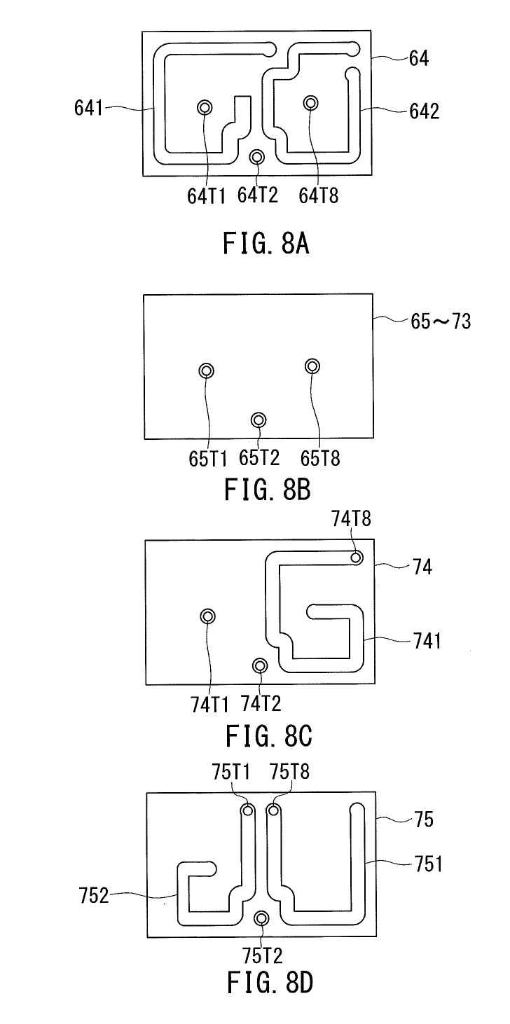

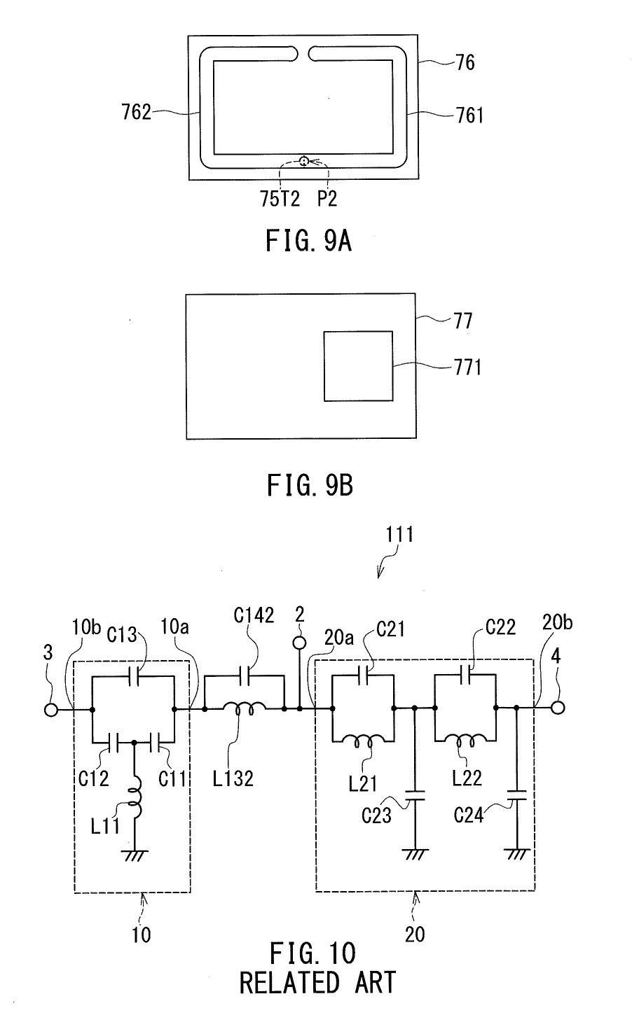

The stack 50 will now be described in detail with reference to FIG. 3 to FIG. 9B. The stack 50 includes twenty-seven dielectric layers stacked on top of one another. The twenty-seven dielectric layers will be referred to as the first to twenty-seventh dielectric layers in the order from bottom to top. FIG. 3 is a perspective internal view of the stack 50. FIG. 4 is an enlarged perspective view of a portion of the interior of the stack 50. FIG. 5A to FIG. 5D illustrate the respective patterned surfaces of the first to fourth dielectric layers. FIG. 6A to FIG. 6D illustrate the respective patterned surfaces of the fifth to eighth dielectric layers. FIG. 7A illustrates the patterned surface of the ninth dielectric layer. FIG. 7B illustrates the patterned surface of each of the tenth and eleventh dielectric layers. FIG. 7C and FIG. 7D illustrate the respective patterned surfaces of the twelfth and thirteenth dielectric layers. FIG. 8A illustrates the patterned surface of the fourteenth dielectric layer. FIG. 8B illustrates the patterned surface of each of the fifteenth to twenty-third dielectric layers. FIG. 8C and FIG. 8D illustrate the respective patterned surfaces of the twenty-fourth and twenty-fifth dielectric layers. FIG. 9A and FIG. 9B illustrate the respective patterned surfaces of the twenty-sixth and twenty-seventh dielectric layers.

As shown in FIG. 5A, the common terminal 102, the first terminal 103, the second terminal 104 and the three ground terminals 105, 106 and 107 are formed on the patterned surface of the first dielectric layer 51. Further, through holes 51T2, 51T3, 51T4, 51T5 and 51T6 are formed in the dielectric layer 51. The through hole 51T2 is used to form the first inductor L31. The through holes 51T3, 51T4, 51T5 and 51T6 are connected to the terminals 103, 104, 105 and 106, respectively. The through hole 51T2 is connected to the terminal 102.

As shown in FIG. 5B, a conductor layer 521 is formed on the patterned surface of the second dielectric layer 52. The conductor layer 521 is used to form the capacitor C23 and the first capacitor C41. Further, through holes 52T2, 52T3, 52T4 and 52T5 are formed in the dielectric layer 52. The through hole 52T2 is used to form the first inductor L31. The through holes 51T2 to 51T4 shown in FIG. 5A are connected to the through holes 52T2 to 52T4, respectively. The through holes 51T5 and 51T6 shown in FIG. 5A and the through hole 52T5 are connected to the conductor layer 521.

As shown in FIG. 5C, conductor layers 531, 532, 533 and 534 are formed on the patterned surface of the third dielectric layer 53. The conductor layers 531, 532 and 533 are used to form the capacitors C12, C23 and C24, respectively. The conductor layer 534 is used to form the first capacitor C41. Further, through holes 53T2, 53T3, 53T4, 53T5 and 53T8 are formed in the dielectric layer 53. The through hole 53T2 is used to form the first inductor L31. The through hole 52T2 shown in FIG. 5B and the through hole 53T2 are connected to the conductor layer 534. The through hole 52T3 shown in FIG. 5B and the through hole 53T3 are connected to the conductor layer 531. The through hole 52T4 shown in FIG. 5B and the through hole 53T4 are connected to the conductor layer 533. The through hole 52T5 shown in FIG. 5B is connected to the through hole 53T5. The through hole 53T8 is connected to the conductor layer 532.

As shown in FIG. 5D, conductor layers 541 and 542 are formed on the patterned surface of the fourth dielectric layer 54. The conductor layer 541 is used to form the capacitor C12. The conductor layer 542 is used to form the capacitors C23 and C24. Further, through holes 54T2, 54T3, 54T4, 54T5, 54T7 and 54T8 are formed in the dielectric layer 54. The through hole 54T2 is used to form the first inductor L31. The through holes 53T2 to 53T4 and 53T8 shown in FIG. 5C are connected to the through holes 54T2 to 54T4 and 54T8, respectively. The through hole 54T5 is connected to the conductor layer 542 and to the through hole 53T5 shown in FIG. 5C. The through hole 54T7 is connected to the conductor layer 541.

As shown in FIG. 6A, conductor layers 551, 552 and 553 are formed on the patterned surface of the fifth dielectric layer 55. The conductor layer 551 is used to form the capacitor C12. The conductor layer 552 is used to form the capacitors C22 and C23. The conductor layer 553 is used to form the capacitor C24. Further, through holes 55T2, 55T3, 55T4, 55T5, 55T7 and 55T8 are formed in the dielectric layer 55. The through hole 55T2 is used to form the first inductor L31. The through holes 54T2, 54T5 and 54T7 shown in FIG. 5D are connected to the through holes 55T2, 55T5 and 55T7, respectively. The through hole 55T3 is connected to the conductor layer 551 and to the through hole 54T3 shown in FIG. 5D. The through hole 55T4 is connected to the conductor layer 553 and to the through hole 54T4 shown in FIG. 5D. The through hole 54T8 shown in FIG. 5D and the through hole 55T8 are connected to the conductor layer 552.

As shown in FIG. 6B, conductor layers 561 and 562 are formed on the patterned surface of the sixth dielectric layer 56. The conductor layer 561 is used to form the capacitors C11 and C12. The conductor layer 562 is used to form the capacitor C22. Further, through holes 56T2, 56T3, 56T4, 56T5, 56T7 and 56T8 are formed in the dielectric layer 56. The through hole 56T2 is used to form the first inductor L31. The through holes 55T2, 55T3, 55T5 and 55T8 shown in FIG. 6A are connected to the through holes 56T2, 56T3, 56T5 and 56T8, respectively. The through hole 56T4 is connected to the conductor layer 562 and to the through hole 55T4 shown in FIG. 6A. The through hole 56T7 is connected to the conductor layer 561 and to the through hole 55T7 shown in FIG. 6A.

As shown in FIG. 6C, conductor layers 571, 572 and 573 are formed on the patterned surface of the seventh dielectric layer 57. The conductor layers 571 and 572 are used to form the capacitor C11 and the second capacitor C42, respectively. Further, through holes 57T1, 57T2, 57T3, 57T4, 57T5, 57T7 and 57T8 are formed in the dielectric layer 57. The through hole 57T2 is used to form the first inductor L31. The through hole 57T1 is connected to the conductor layer 571. The through hole 57T2 is connected to the conductor layer 572 and to the through hole 56T2 shown in FIG. 6B. The through holes 56T3 to 56T5 and 56T7 shown in FIG. 6B are connected to the through holes 57T3 to 57T5 and 57T7, respectively. The through hole 56T8 shown in FIG. 6B and the through hole 57T8 are connected to the conductor layer 573.

As shown in FIG. 6D, a conductor layer 581 is formed on the patterned surface of the eighth dielectric layer 58. The conductor layer 581 is used to form the capacitor C13 and the second capacitor C42. Further, through holes 58T1, 58T2, 58T3, 58T4, 58T5, 58T7 and 58T8 are formed in the dielectric layer 58. The through hole 58T2 is used to form the first inductor L31. The through hole 57T1 shown in FIG. 6C and the through hole 58T1 are connected to the conductor layer 581. The through holes 57T2 to 57T5, 57T7 and 57T8 shown in FIG. 6C are connected to the through holes 58T2 to 58T5, 58T7 and 58T8, respectively.

As shown in FIG. 7A, a conductor layer 591 is formed on the patterned surface of the ninth dielectric layer 59. The conductor layer 591 is used to form the capacitor C13. Further, through holes 59T1, 59T2, 59T4, 59T5, 59T7 and 59T8 are formed in the dielectric layer 59. The through hole 59T2 is used to form the first inductor L31. The through holes 58T1, 58T2, 58T4, 58T5, 58T7 and 58T8 shown in FIG. 6D are connected to the through holes 59T1, 59T2, 59T4, 59T5, 59T7 and 59T8, respectively. The through hole 58T3 shown in FIG. 6D is connected to the conductor layer 591.

As shown in FIG. 7B, through holes 60T1, 60T2, 60T4, 60T5, 60T7 and 60T8 are formed in each of the tenth and eleventh dielectric layers 60 and 61. The through holes 60T2 formed in the dielectric layers 60 and 61 are used to form the first inductor L31. In the dielectric layers 60 and 61, every vertically adjacent through holes assigned the same reference symbols are connected to each other. The through holes 59T1, 59T2, 59T4, 59T5, 59T7 and 59T8 shown in FIG. 7A are respectively connected to the through holes 60T1, 60T2, 60T4, 60T5, 60T7 and 60T8 formed in the dielectric layer 60.

As shown in FIG. 7C, conductor layers 621 and 622 are formed on the patterned surface of the twelfth dielectric layer 62. The conductor layers 621 and 622 are used to form the inductors L11 and L22, respectively. Each of the conductor layers 621 and 622 has a first end and a second end. Further, through holes 62T1, 62T2, 62T4, 62T5, 62T6, 62T7 and 62T8 are formed in the dielectric layer 62. The through holes 62T2 and 62T8 are used to form the first inductor L31 and the inductor L23, respectively. The through holes 60T1, 60T2, 60T4 and 60T5 formed in the dielectric layer 61 shown in FIG. 7B are connected to the through holes 62T1, 62T2, 62T4 and 62T5, respectively. The through hole 62T6 is connected to a portion of the conductor layer 622 near the first end thereof. The through hole 62T7 is connected to a portion of the conductor layer 621 near the first end thereof. The through hole 62T8 is connected to a portion of the conductor layer 622 near the second end thereof and to the through hole 60T8 formed in the dielectric layer 61 shown in FIG. 7B. The through hole 60T7 formed in the dielectric layer 61 shown in FIG. 7B is connected to a portion of the conductor layer 621 near the second end thereof.

As shown in FIG. 7D, conductor layers 631 and 632 are formed on the patterned surface of the thirteenth dielectric layer 63. The conductor layers 631 and 632 are used to form the inductors L11 and L22, respectively. Each of the conductor layers 631 and 632 has a first end and a second end. Further, through holes 63T1, 63T2, 63T4, 63T5, 63T6, 63T7 and 63T8 are formed in the dielectric layer 63. The through holes 63T2 and 63T8 are used to form the first inductor L31 and the inductor L23, respectively. The through holes 62T1, 62T2, 62T4, 62T5 and 62T8 shown in FIG. 7C are connected to the through holes 63T1, 63T2, 63T4, 63T5 and 63T8, respectively. The through hole 63T6 is connected to a portion of the conductor layer 632 near the first end thereof. The through hole 63T7 is connected to a portion of the conductor layer 631 near the first end thereof. The through hole 62T6 shown in FIG. 7C is connected to a portion of the conductor layer 632 near the second end thereof. The through hole 62T7 shown in FIG. 7C is connected to a portion of the conductor layer 631 near the second end thereof.

As shown in FIG. 8A, conductor layers 641 and 642 are formed on the patterned surface of the fourteenth dielectric layer 64. The conductor layers 641 and 642 are used to form the inductors L11 and L22, respectively. Each of the conductor layers 641 and 642 has a first end and a second end. Further, through holes 64T1, 64T2 and 64T8 are formed in the dielectric layer 64. The through holes 64T2 and 64T8 are used to form the first inductor L31 and the inductor L23, respectively. The through holes 63T1, 63T2 and 63T8 shown in FIG. 7D are connected to the through holes 64T1, 64T2 and 64T8, respectively. The through hole 63T4 shown in FIG. 7D is connected to a portion of the conductor layer 642 near the first end thereof. The through hole 63T5 shown in FIG. 7D is connected to a portion of the conductor layer 641 near the first end thereof. The through hole 63T6 shown in FIG. 7D is connected to a portion of the conductor layer 642 near the second end thereof. The through hole 63T7 shown in FIG. 7D is connected to a portion of the conductor layer 641 near the second end thereof.

As shown in FIG. 8B, through holes 65T1, 65T2 and 65T8 are formed in each of the fifteenth to twenty-third dielectric layers 65 to 73. The through holes 65T2 formed in the dielectric layers 65 to 73 are used to form the first inductor L31. The through holes 65T8 formed in the dielectric layers 65 to 73 are used to form the inductor L23. In the dielectric layers 65 to 73, every vertically adjacent through holes assigned the same reference symbols are connected to each other. The through holes 64T1, 64T2 and 64T8 shown in FIG. 8A are respectively connected to the through holes 65T1, 65T2 and 65T8 formed in the dielectric layer 65.

As shown in FIG. 8C, a conductor layer 741 is formed on the patterned surface of the twenty-fourth dielectric layer 74. The conductor layer 741 is used to form the inductor L21, and has a first end and a second end. Further, through holes 74T1, 74T2 and 74T8 are formed in the dielectric layer 74. The through hole 74T2 is used to form the first inductor L31. The through holes 65T1 and 65T2 formed in the dielectric layer 73 shown in FIG. 8B are connected to the through holes 74T1 and 74T2, respectively. The through hole 74T8 is connected to a portion of the conductor layer 741 near the first end thereof. The through hole 65T8 formed in the dielectric layer 73 shown in FIG. 8B is connected to a portion of the conductor layer 741 near the second end thereof.

As shown in FIG. 8D, conductor layers 751 and 752 are formed on the patterned surface of the twenty-fifth dielectric layer 75. The conductor layers 751 and 752 are used to form the inductor L21 and the second inductor L32, respectively. Each of the conductor layers 751 and 752 has a first end and a second end. Further, through holes 75T1, 75T2 and 75T8 are formed in the dielectric layer 75. The through hole 75T2 is used to form the first inductor L31. The through hole 75T1 is connected to a portion of the conductor layer 752 near the first end thereof. The through hole 74T2 shown in FIG. 8C is connected to the through hole 75T2. The through hole 75T8 is connected to a portion of the conductor layer 751 near the first end thereof. The through hole 74T1 shown in FIG. 8C is connected to a portion of the conductor layer 752 near the second end thereof. The through hole 74T8 shown in FIG. 8C is connected to a portion of the conductor layer 751 near the second end thereof.

As shown in FIG. 9A, conductor layers 761 and 762 are formed on the patterned surface of the twenty-sixth dielectric layer 76. The conductor layers 761 and 762 are used to form the inductor L21 and the second inductor L32, respectively. Each of the conductor layers 761 and 762 has a first end and a second end. The first end of the conductor layer 761 and the first end of the conductor layer 762 are connected to each other. In FIG. 9A the boundary between the conductor layers 761 and 762 is shown by a dotted line. The through hole 75T1 shown in FIG. 8D is connected to a portion of the conductor layer 762 near the second end thereof. The through hole 75T2 shown in FIG. 8D is connected to a portion of the conductor layer 761 near the first end thereof and to a portion of the conductor layer 762 near the first end thereof. The through hole 75T8 shown in FIG. 8D is connected to a portion of the conductor layer 761 near the second end thereof.

As shown in FIG. 9B, a mark 771 is formed on the patterned surface of the twenty-seventh dielectric layer 77.

The stack 50 shown in FIG. 2 is formed by stacking the first to twenty-seventh dielectric layers 51 to 77 such that the patterned surface of the first dielectric layer 51 also serves as the bottom surface 50B of the stack 50.

FIG. 3 shows the interior of the stack 50. FIG. 4 provides an enlarged view of a portion of the interior of the stack 50.

Correspondences of the circuit components of the branching filter 1 shown in FIG. 1 with the components inside the stack 50 shown in FIGS. 5A to 9B will now be described. The first inductor L31 of the connection path 30 is constructed of the through holes 51T2, 52T2, 53T2, 54T2, 55T2, 56T2, 57T2, 58T2 and 59T2 shown in FIGS. 5A to 7A, the two through holes 60T2 formed in the dielectric layers 60 and 61 shown in FIG. 7B, the through holes 62T2, 63T2 and 64T2 shown in FIGS. 7C to 8A, the nine through holes 65T2 formed in the dielectric layers 65 to 73 shown in FIG. 8B, and the through holes 74T2 and 75T2 shown in FIGS. 8C and 8D. The above-listed through holes 51T2 to 75T2 are connected in series. A set of the through holes 51T2 to 75T2 will hereinafter be referred to as the through hole line T31. The through hole 51T2 is connected to the common terminal 102. An end of the through hole 51T2 contacting the common terminal 102 corresponds to the first end L31a of the first inductor L31.

The conductor layer 534 is connected to the through hole line T31 at a position between the through holes 52T2 and 53T2. As shown in FIGS. 3, 4 and 5C, the position in the through hole line T31 at which the conductor layer 534 is connected to the through hole line T31 corresponds to the first branch point P1.

The conductor layer 572 is connected to the through hole line T31 at a position between the through holes 56T2 and 57T2. As shown in FIGS. 3, 4 and 6C, the position in the through hole line T31 at which the conductor layer 572 is connected to the through hole line T31 corresponds to the third branch point P3.

The conductor layers 761 and 762 are connected to the through hole 75T2 and thereby connected to the through hole line T31. As shown in FIGS. 3 and 9A, the position in the through hole line T31 at which the conductor layers 761 and 762 are connected to the through hole line T31 corresponds to the second branch point P2. An end of the through hole 75T2 contacting the conductor layers 761 and 762 corresponds to the second end L31b of the first inductor L31.

The second inductor L32 of the connection path 30 is constructed of the conductor layers 752 and 762 and the through hole 75T1, which are shown in FIGS. 8D and 9A. The conductor layer 762 is connected to the second branch point P2.

The first capacitor C41 is constructed of the conductor layers 521 and 534 shown in FIGS. 5B and 5C, and the dielectric layer 52 interposed between the conductor layers 521 and 534. The conductor layer 521 is connected to the ground terminals 105 and 106 via the through holes 51T5 and 51T6, respectively. The conductor layer 534 is connected to the first branch point P1.

The second capacitor C42 is constructed of the conductor layers 572 and 581 shown in FIGS. 6C and 6D, and the dielectric layer 57 interposed between the conductor layers 572 and 581. The conductor layer 572 is connected to the third branch point P3. The conductor layer 581 is connected to the conductor layer 752, which constitutes part of the second inductor L32, via the through holes 58T1 and 59T1, the two through holes 60T1 formed in the dielectric layers 60 and 61, the through holes 62T1, 63T1 and 64T1, the nine through holes 65T1 formed in the dielectric layers 65 to 73, and the through hole 74T1. The above-listed through holes 58T1 to 74T1 are connected in series. A set of the through holes 58T1 to 74T1 will hereinafter be referred to as the through hole line T32. The capacitor C43 is a stray capacitance generated between the conductor layer 581 and the ground terminal 107.

The capacitor C11 of the first filter 10 is constructed of the conductor layers 561 and 571 shown in FIGS. 6B and 6C, and the dielectric layer 56 interposed between the conductor layers 561 and 571. The capacitor C12 of the first filter 10 is constructed of the conductor layers 531, 541, 551 and 561 shown in FIGS. 5C to 6B, the dielectric layer 53 interposed between the conductor layers 531 and 541, the dielectric layer 54 interposed between the conductor layers 541 and 551, and the dielectric layer 55 interposed between the conductor layers 551 and 561. The conductor layer 531 is connected to the first terminal 103 via the through holes 51T3 and 52T3. The conductor layer 541 is connected to the conductor layer 561 via the through holes 54T7 and 55T7. The conductor layer 551 is connected to the conductor layer 531 via the through holes 53T3 and 54T3. The conductor layer 571 is connected to the conductor layer 752, which constitutes part of the second inductor L32, via the through hole 57T1, the conductor layer 581 and the through hole line T32.

The capacitor C13 of the first filter 10 is constructed of the conductor layers 581 and 591 shown in FIGS. 6D and 7A, and the dielectric layer 58 interposed between the conductor layers 581 and 591. The conductor layer 581 is connected via the through hole line T32 to the conductor layer 752 constituting part of the second inductor L32. The conductor layer 591 is connected to the first terminal 103 via the through holes 51T3 and 52T3, the conductor layer 531, and the through holes 53T3, 54T3, 55T3, 56T3, 57T3 and 58T3.

The inductor L11 of the first filter 10 is constructed of the conductor layers 621, 631 and 641 shown in FIGS. 7C to 8A, and the through holes 62T7 and 63T7. The conductor layer 621 is connected to the conductor layer 561, which constitutes part of each of the capacitors C11 and C12, via the through holes 56T7, 57T7, 58T7 and 59T7, and the two through holes 60T7 formed in the dielectric layers 60 and 61. The conductor layer 641 is connected to the ground terminal 105 via the through hole 51T5, the conductor layer 521, the through holes 52T5, 53T5, 54T5, 55T5, 56T5, 57T5, 58T5 and 59T5, the two through holes 60T5 formed in the dielectric layers 60 and 61, and the through holes 62T5 and 63T5.

The inductor L21 of the second filter 20 is constructed of the conductor layers 741, 751 and 761 shown in FIGS. 8C to 9A, and the through holes 74T8 and 75T8. The conductor layer 761 is connected to the second branch point P2. The capacitor C21 of the second filter 20 is a stray capacitance arising from the inductor L21.

The inductor L22 of the second filter 20 is constructed of the conductor layers 622, 632 and 642 shown in FIGS. 7C to 8A, and the through holes 62T6 and 63T6. The conductor layer 642 is connected to the second terminal 104 via the through holes 51T4, 52T4, 53T4, 54T4, 55T4, 56T4, 57T4, 58T4 and 59T4, the two through holes 60T4 formed in the dielectric layers 60 and 61, and the through holes 62T4 and 63T4.

The first inductor L23 of the second filter 20 is constructed of the through holes 62T8, 63T8 and 64T8 shown in FIGS. 7C to 8A, and the nine through holes 65T8 formed in the dielectric layers 65 to 73 shown in FIG. 8B. The above-listed through holes 62T8 to 65T8 are connected in series. A set of the through holes 62T8 to 65T8 will hereinafter be referred to as the through hole line T23. The through hole 62T8 is connected to the conductor layer 622 constituting part of the inductor L22. The through hole 65T8 formed in the dielectric layer 73 is connected to the conductor layer 741 constituting part of the inductor L21.

The capacitor C22 of the second filter 20 is constructed of the conductor layers 552 and 562 shown in FIGS. 6A and 6B, and the dielectric layer 55 interposed between the conductor layers 552 and 562. The capacitor C23 of the second filter 20 is constructed of the conductor layers 521, 532, 542 and 552 shown in FIGS. 5B to 6A, the dielectric layer 52 interposed between the conductor layers 521 and 532, the dielectric layer 53 interposed between the conductor layers 532 and 542, and the dielectric layer 54 interposed between the conductor layers 542 and 552. The conductor layer 521 is connected to the ground terminals 105 and 106 via the through holes 51T5 and 51T6, respectively. The conductor layer 532 is connected to the conductor layer 552 via the through holes 53T8 and 54T8. The conductor layer 542 is connected to the conductor layer 521 via the through holes 52T5, 53T5 and 54T5. The conductor layer 552 is connected to the conductor layer 622 constituting part of the inductor L22 and to the through hole 62T8 constituting part of the inductor L23, via the through holes 55T8 and 56T8, the conductor layer 573, the through holes 57T8, 58T8 and 59T8, and the two through holes 60T8 formed in the dielectric layers 60 and 61. The conductor layer 562 is connected to the second terminal 104 via the through holes 51T4 and 52T4, the conductor layer 533, and the through holes 53T4, 54T4 and 55T4.

The capacitor C24 of the second filter 20 is constructed of the conductor layers 533, 542 and 553 shown in FIGS. 5C to 6A, the dielectric layer 53 interposed between the conductor layers 533 and 542, and the dielectric layer 54 interposed between the conductor layers 542 and 553. The conductor layer 533 is connected to the second terminal 104 via the through holes 51T4 and 52T4. The conductor layer 542 is connected to the ground terminal 105 via the through hole 51T5, the conductor layer 521, and the through holes 52T5 and 53T5. The conductor layer 553 is connected to the conductor layer 533 via the through holes 53T4 and 54T4.

The features and effects of the branching filter 1 according to the present embodiment will now be described with reference to two comparative examples. First, reference is made to FIG. 10 to describe the configuration of a branching filter 111 of a first comparative example. The branching filter 111 was designed without consideration of a stray inductance or stray capacitance resulting from the structure. The branching filter 111 includes none of the first inductor L31, the first capacitor C41, the inductor L23 and the capacitor C43 of the branching filter 1 according to the present embodiment. The branching filter 111 includes an inductor L132 and a capacitor C142 in place of the inductor L32 and the capacitor C42 of the branching filter 1. The first end 20a of the second filter 20 is connected to the common port 2.

In the branching filter 111, one end of the inductor L132 and one end of the capacitor C142 are connected to the common port 2. The other end of the inductor L132 and the other end of the capacitor C142 are connected to the first end 10a of the first filter 10. The inductor L132 and the capacitor C142 constitute a parallel resonant circuit. This parallel resonant circuit has a resonant frequency higher than the first frequency band. Thus, the insertion loss characteristic of the first signal path leading to the first signal port 3 from the common port 2 shows an attenuation pole at the resonant frequency of the parallel resonant circuit. The parallel resonant circuit functions as a low-pass filter. In the branching filter 111, the parallel resonant circuit and the first filter 10 constitute a band-pass filter for selectively passing the first signal of a frequency within the first frequency band.

Now, a description will be given of a problem arising in the case of constructing the branching filter 111 using a stack with a plurality of terminals arranged on the bottom surface thereof. In such a case, the conductor layer for forming the inductor L21 and the conductor layer for forming the inductor L132 are preferably disposed away from the bottom surface of the stack so as not to interrupt passage of a magnetic flux generated by each of the inductors L21 and L132. To achieve such a layout, a common path connecting the common port 2 and a branch point between the path to the first filter 10 and the path to the second filter 20 as viewed from the common port 2 needs to be constructed of a through hole line composed of a plurality of through holes connected in series. This configuration, however, gives rise to the problem that an inductance of the through hole line causes an impedance mismatch between the common port 2 and at least one of the first and second filters 10 and 20, thereby causing degradation in the performance of the branching filter 111 as compared to that as designed.

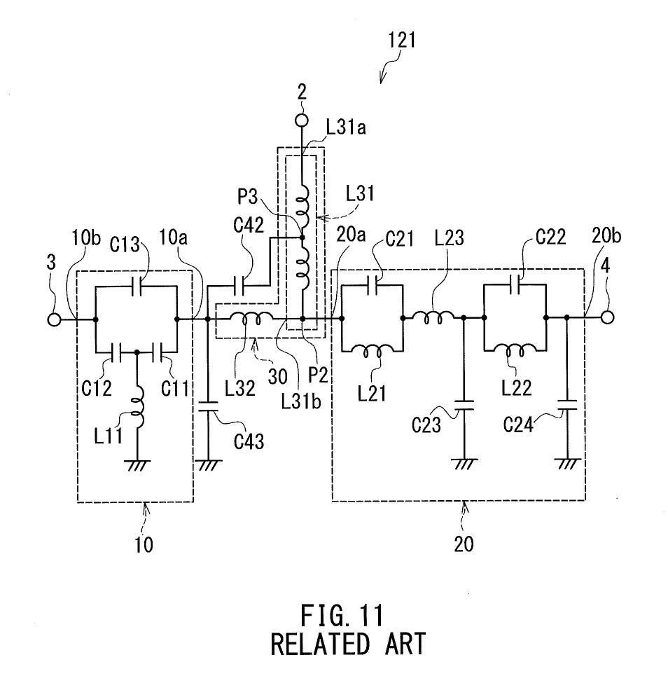

Next, reference is made to FIG. 11 to describe the configuration of a branching filter 121 of a second comparative example. The branching filter 121 is configured by omitting the first capacitor C41 from the branching filter 1 according to the present embodiment. The branching filter 121 includes the first inductor L31 constructed of the through hole line T31, as does the branching filter 1 according to the present embodiment. In the branching filter 121, the capacitor C42 is provided between the branch point P3 and the first end 10a of the first filter 10 in the first inductor L31. The inductor L32, the capacitor C42, and a portion of the first inductor L31 extending from the branch point P3 to the second end L31b constitute a parallel resonant circuit.

In the branching filter 121, the impedance characteristic of the second signal path leading to the second signal port 4 from the common port 2 is adjustable by changing the position of the branch point P2. Further, the impedance characteristic of the first signal path leading to the first signal port 3 from the common port 2 is adjustable by changing the position of the branch point P3. The branching filter 121 thus enables the impedance characteristics of the first and second signal paths to be adjusted independently of each other.

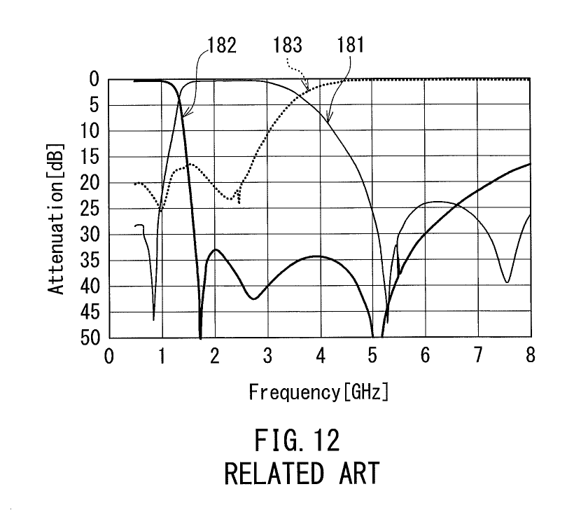

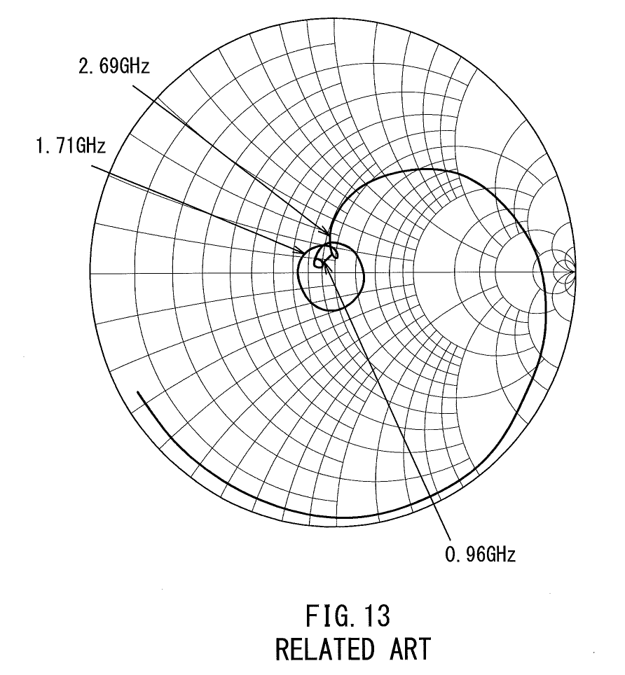

An example of characteristics of the branching filter 121 will now be described with reference to FIG. 12 and FIG. 13. FIG. 12 is a characteristic diagram illustrating an example of characteristics of the branching filter 121. In FIG. 12, the horizontal axis represents frequency, and the vertical axis represents attenuation. In FIG. 12, the curve 181 represents the insertion loss characteristic of the first signal path, the curve 182 represents the insertion loss characteristic of the second signal path, and the curve 183 represents the return loss characteristic as viewed from the common port 2 toward the filters 10 and 20. It is assumed here that the first frequency band ranges from approximately 1.7 GHz to approximately 2.7 GHz, and the second frequency band ranges from approximately 0.7 GHz to approximately 0.96 GHz.

FIG. 13 is a characteristic diagram illustrating an example of the impedance characteristic of the branching filter 121. More specifically, FIG. 13 is a Smith chart showing the impedance characteristic as viewed from the common port 2 toward the filters 10 and 20. FIG. 13 indicates the points of 0.96 GHz, 1.71 GHz and 2.69 GHz. The characteristics shown in FIGS. 12 and 13 were determined by simulation.

The impedance characteristic shown in FIG. 13 indicates that in the first and second frequency bands, the imaginary part of the reflection coefficient has a positive value, thereby making the absolute value of the reflection coefficient larger than 0 to some extent. For this reason, the return loss characteristic 183 shown in FIG. 12 fails to show a sufficiently large attenuation in the first and second frequency bands. These phenomena are due to an inductance of the first inductor L31 present in the path from the common port 2 to each of the first and second filters 10 and 20.

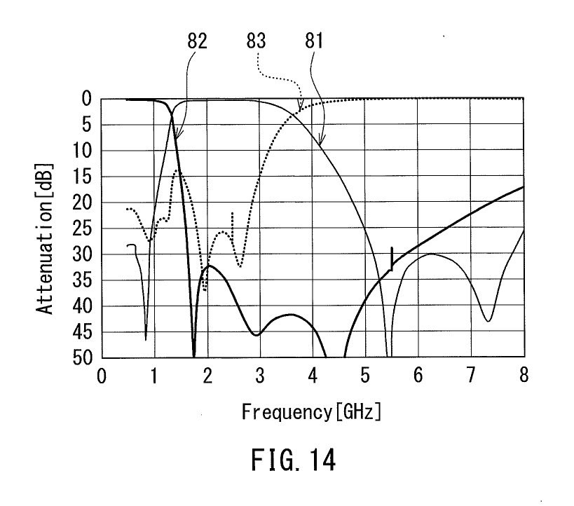

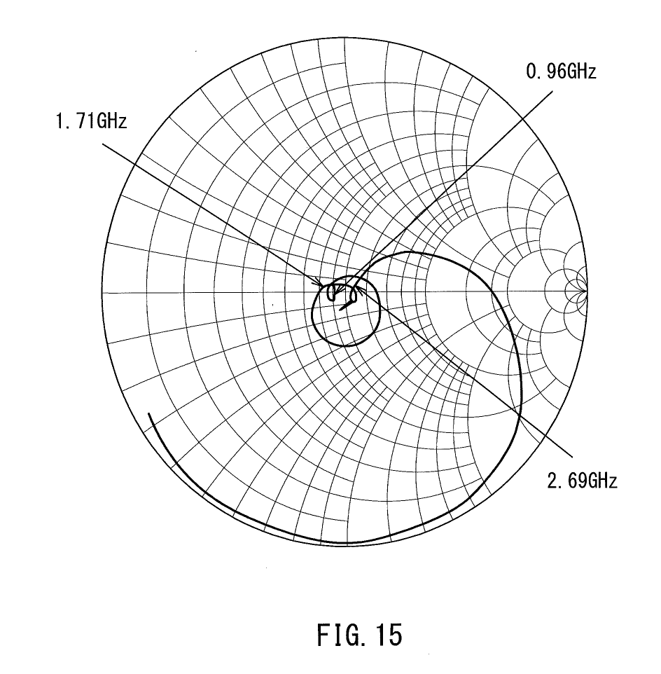

Now, reference is made to FIGS. 14 and 15 to describe an example of characteristics of the branching filter 1 according to the present embodiment. FIG. 14 is a characteristic diagram illustrating an example of characteristics of the branching filter 1. In FIG. 14, the horizontal axis represents frequency, and the vertical axis represents attenuation. In FIG. 14, the curve 81 represents the insertion loss characteristic of the first signal path, the curve 82 represents the insertion loss characteristic of the second signal path, and the curve 83 represents the return loss characteristic as viewed from the common port 2 toward the filters 10 and 20. It is assumed here that the first frequency band ranges from approximately 1.7 GHz to approximately 2.7 GHz, and the second frequency band ranges from approximately 0.7 GHz to approximately 0.96 GHz.

FIG. 15 is a characteristic diagram illustrating an example of the impedance characteristic of the branching filter 1. More specifically, FIG. 15 is a Smith chart showing the impedance characteristic as viewed from the common port 2 toward the filters 10 and 20. FIG. 15 indicates the points of 0.96 GHz, 1.71 GHz and 2.69 GHz. The characteristics shown in FIGS. 14 and 15 were determined by simulation.

The impedance characteristic shown in FIG. 15 indicates that in the first and second frequency bands, the imaginary part of the reflection coefficient has a value closer to 0, and thus the absolute value of the reflection coefficient is also closer to 0 when compared with the impedance characteristic shown in FIG. 13. As a result, the return loss characteristic 83 shown in FIG. 14 shows greater attenuation in the first and second frequency bands when compared with the return loss characteristic 183 shown in FIG. 12.

Thus, by virtue of the provision of the first capacitor C41, the branching filter 1 according to the present embodiment exhibits favorable characteristics even when the path leading to at least one of the two filters 10 and 20 (that is, at least the filter 10 in the present embodiment) from the common port 2 has an inductance.

The reason why the provision of the first capacitor C41 improves the characteristics of the branching filter 1 compared to the branching filter 121 can be qualitatively explained as follows. The first inductor L31 and the first capacitor C41 act to move a point at which the absolute value of the reflection coefficient is zero or near zero on the Smith chart in mutually opposite directions. More specifically, the first inductor L31 acts to move the aforementioned point on the Smith chart in a direction in which the imaginary part of the reflection coefficient increases, that is, in an upward direction, when compared with the case where the first inductor L31 is not provided. On the other hand, the first capacitor C41 acts to move the aforementioned point on the Smith chart in a direction in which the imaginary part of the reflection coefficient decreases, that is, in a downward direction, when compared with the case where the first capacitor C41 is not provided.

The branching filter 1 is configured by adding the first capacitor C41 to the branching filter 121 which exhibits the characteristic shown in FIG. 13 due to the first inductor. L31 having an inductance. Such a configuration of the branching filter 1 brings the value of the imaginary part of the reflection coefficient closer to zero, thus bringing the absolute value of the reflection coefficient also closer to zero, as shown in FIG. 15.

The other effects of the branching filter 1 resulting from the first capacitor C41 will now be described. When compared with the insertion loss characteristic 182 of the second signal path in the branching filter 121 shown in FIG. 12, the insertion loss characteristic 82 of the second signal path in the branching filter 1 shown in FIG. 14 exhibits a greater attenuation in a frequency range higher than the second frequency band. Further, when compared with the insertion loss characteristic 181 of the first signal path in the branching filter 121 shown in FIG. 12, the insertion loss characteristic 81 of the first signal path in the branching filter 1 shown in FIG. 14 exhibits a greater attenuation in a frequency range higher than the first frequency band. These facts also indicate that the branching filter 1 according to the present embodiment exhibits better characteristics than those of the branching filter 121.

Further effects of the branching filter 1 according to the present embodiment will now be described. In the branching filter 1, the first capacitor C41 is connected to the first inductor L31 at the first branch point P1 located at any position in the first inductor L31 inclusive of the first end L31a and the second end L31b. In the present embodiment, adjustments of the impedance characteristics of the first signal path and the second signal path are possible by changing the position of the first branch point P1.

In the present embodiment, the first inductor L31 is constructed of the through hole line T31, in particular. It is thus possible to easily change the position of the first branch point P1 by changing the through hole to be connected with the conductor layer 534 for constructing the capacitor C41, among the through holes constituting the through hole line T31, during the structure design phase of the branching filter 1.

Further, in the branching filter 1, the second filter 20 is connected to the first inductor L31 at the second branch point P2 located at any position in the first inductor L31 inclusive of the first end L31a and the second end L31b. In the present embodiment, changing the position of the second branch point P2 changes the inductance of the path leading to the second filter 20 from the common port 2, thereby making it possible to adjust the impedance characteristic of the second signal path. The present embodiment thus enables the impedance characteristics of the first and second signal paths to be adjusted independently of each other.

FIG. 3 and FIG. 9A illustrate an example in which the conductor layer 761 for constructing the inductor L21 and the conductor layer 762 for constructing the inductor L32 are located on the same dielectric layer 76. Alternatively, in the present embodiment, the conductor layers 761 and 762 may be located on mutually different dielectric layers. Then, among the through holes constituting the through hole line T31, the through hole to be connected with the conductor layer 761 can be changed during the structure design phase of the branching filter 1. This allows easy changing of the position of the second branch point P2.

Further, in the branching filter 1, the capacitor C42 is provided between the branch point P3 and the first end 10a of the first filter 10 in the first inductor L31. The inductor L32, the capacitor C42, and a portion of the first inductor L31 extending from the branch point P3 to the second end L31b constitute a parallel resonant circuit. The parallel resonant circuit has a resonant frequency higher than the first frequency band. Thus, the insertion loss characteristic of the first signal path shows an attenuation pole at the resonant frequency of the parallel resonant circuit. The parallel resonant circuit functions as a low-pass filter. In the branching filter 1, the parallel resonant circuit and the first filter 10 constitute a band-pass filter for selectively passing the first signal of a frequency within the first frequency band.

In the present embodiment, the impedance characteristic of the first signal path is adjustable by changing the position of the third branch point P3. The present embodiment thus enables the impedance characteristics of the first and second signal paths to be adjusted independently of each other.

In the present embodiment, since the first inductor L31 is constructed of the through hole line T31, the position of the third branch point P3 is easily changeable by changing the through hole to be connected with the conductor layer 572 for constructing the capacitor C42, among the through holes constituting the through hole line T31, during the structure design phase of the branching filter 1.

The present invention is not limited to the above-described embodiment, and various modifications may be made thereto. For example, characteristics of the first filter and the second filter in the present invention are not limited to those illustrated in the foregoing embodiment, and can be freely designed as far the requirements of the appended claims are met.

Obviously, many modifications and variations of the present invention are possible in the light of the above teachings. Thus, it is to be understood that, within the scope of the appended claims and equivalents thereof, the invention may be practiced in other than the foregoing most preferable embodiment.

What is claimed is:

1. A branching filter comprising:
a common port;
a first signal port;
a second signal port;
a first filter provided between the common port and the first signal port, and configured to selectively pass a signal of a frequency within a first passband;
a second filter provided between the common port and the second signal port, and configured to selectively pass a signal of a frequency within a second passband different from the first passband;
a connection path including a first inductor, for connecting the common port and the first filter; and
a first capacitor provided between the connection path and a ground, wherein
the second filter is connected to the connection path,
the first inductor has a first end closer to the common port and a second end closer to the first filter, and
the first capacitor is connected to the first inductor at a first branch point located at any position in the first inductor inclusive of the first end and the second end.

2. The branching filter according to claim 1, wherein
the connection path further includes a second inductor provided between the first inductor and the first filter, and
the second filter is connected to the first inductor at a second branch point located at any position in the first inductor inclusive of the first end and the second end.

3. The branching filter according to claim 2, wherein the first branch point is located between the first end and the second branch point, inclusive, in the first inductor.

4. The branching filter according to claim 2, further comprising a second capacitor provided between the first filter and a third branch point located at any position in the first inductor inclusive of the first end and the second end.

5. The branching filter according to claim 1, further comprising a stack for constructing the first filter, the second filter, the connection path and the first capacitor, the stack including a plurality of dielectric layers and a plurality of conductor layers stacked on each other.

6. The branching filter according to claim 5, further comprising a second capacitor constructed of the stack and provided between the first filter and a third branch point located at any position in the first inductor inclusive of the first end and the second end.

7. The branching filter according to claim 5, wherein the first inductor is constructed of a plurality of through holes connected in series.

8. The branching filter according to claim 1, wherein the second passband is a frequency band lower than the first passband.
